(19) United States
(12) Patent Application Publication
(10) Pub. No.: US 2024/0322786 A1
(43) Pub. Date: Sep. 26, 2024

(54) Bulk Acoustic Wave (BAW) Microresonator Package

(71) Applicant: Texas Instruments Incorporated, Dallas, TX (US)

(72) Inventors: John Carlo Molina, Limay (PH); Laura May Antoinette Dela Paz Clemente, Mabalacat City (PH); Ray Fredric De Asis, Mabalcat City (PH)

(21) Appl. No.: 18/189,388

(22) Filed: Mar. 24, 2023

(51) Int. Cl. H03H 9/10; H03H 3/02; H03H 9/02; H03H 9/05

(52) U.S. Cl. CPC H03H 9/1042; H03H 3/02; H03H 9/02133; H03H 9/0523; H03H 9/0533; H03H 9/0547

(57) ABSTRACT

A semiconductor package comprises a leadframe having a die attach pad and one or more leads and a semiconductor die electrically connected to the die attach pad. A BAW device is attached to the semiconductor die. A mold compound surrounds the first semiconductor die and covers portions of the leadframe and a first portion of a top surface of the semiconductor die. The mold compound has a cavity area. The mold compound does not cover the BAW device or a second portion of the top surface of the semiconductor die in the cavity area. A glob top material is disposed within the cavity area. The glob top material covers the BAW device and the second portion of the top of the semiconductor die.

### BACKGROUND

Bulk Acoustic Wave (BAW) resonators are electromechanical devices in which standing acoustic waves are generated by an electrical signal in the bulk of a piezoelectric material. BAW devices use a piezoelectric effect to convert electrical energy into mechanical energy resulting from an applied radio frequency (RF) voltage. BAW devices generally operate at a mechanical resonant frequency that is defined as the frequency for which the half wavelength of sound waves propagating in the device is equal to the total piezoelectric layer thickness for a given velocity of sound in the piezoelectric material. BAW resonators operating in the GHz range (e.g., at about 2 GHz) generally have physical dimensions of tens of microns in diameter with thicknesses of a few microns. The piezoelectric layer of the BAW device is acoustically isolated from the substrate.

Typical packaged electronic BAW devices include a die with one or more electronic components mounted to a die pad within a molded package structure. Bond wires connect die pads of the die with leads that provide external access for soldering to a host printed circuit board (PCB). Glob top materials are used to cover and protect BAW dies or other components of an integrated circuit against contamination and mechanical stress. However, the glob top material may have undesired delamination from the molding material when the materials are curing.

### SUMMARY

In an example electronic package apparatus, mold compound is removed to create a cavity via laser ablation prior the attachment and integration of a BAW die into the package. The process includes attachment of a bottom die to a leadframe, wire bonding the bottom die to the leadframe, molding the bottom die and leadframe, laser ablation of the molding to create a cavity, attaching a BAW die to the bottom die, and applying a glob top encapsulant over the BAW die to improve the frequency shift margins.

In an arrangement, a semiconductor package comprises a segment of a leadframe having a die attach pad and one or more leads, a semiconductor die electrically connected to the die attach pad; a BAW device attached to (and electrically connected to) the semiconductor die, a mold compound surrounding the first semiconductor die and covering portions of the leadframe and a first portion of a top surface of the semiconductor die, a cavity formed in the mold compound, the cavity exposing the BAW device and a second portion of the top surface of the semiconductor die from the mold compound, and a glob top material disposed within the cavity, the glob top material covering the BAW device and the second portion of the top of the semiconductor die. The semiconductor die is electrically connected to the one or more leads by bond wires that are encapsulated by the mold compound. The semiconductor package may be a quad-flat no-leads (QFN) package.

The cavity has a first height above the semiconductor die, and the glob top material has a second height above the semiconductor die that is less than the first height. The glob top material does not fill the cavity in the mold compound. The mold compound does not cover a top surface of the glob top material.

The BAW device has as top surface and a bottom surface, the bottom surface attached to the top surface of the semiconductor die, the top surface having one or more bond pads, the one or more bond pads electrically connected to contact pads on the semiconductor die by bond wires.

Alternatively, the BAW device is flip-chip mounted on the semiconductor die. The semiconductor package further comprises bond pads on an active surface of the BAW device. The active surface of the BAW device faces the top surface of the semiconductor die. Contact pads are located on the top surface of the semiconductor die, and metal bumps, such as copper, electrically connecting the bond pads to the contact pads.

The glob top is a stress absorbing material that isolates the BAW device from stresses and vibrations in the electronic package. The glob top is a low elastic modulus material that is different from a material used for the mold compound.

In an example method for assembling a stacked-die package, process steps comprise performing a first die attach process that attaches a first side of a first semiconductor die to a die attach pad of a leadframe, performing a first wire bonding process that connects a first bond wire between a first conductive pad of the first semiconductor die to a lead of the leadframe, performing a molding process that encloses a portion of the die attach pad, a portion of the lead, first semiconductor die, and the first bond wire in a mold compound, creating a cavity in the mold compound, the cavity extending from a second side of the first semiconductor die to a top of the mold compound, performing a second die attach process that attaches a second semiconductor die to the second side of the first semiconductor die, and performing a deposition process that deposits a stress absorbing material in the cavity to cover the second semiconductor die. The cavity in the mold compound is created using laser ablation.

The method further comprises applying a laser stop metal to a portion of the second surface of the first semiconductor die before the molding process, and chemically removing an exposed segment of the laser stop metal after the cavity has been created. The cavity in the mold compound is created using laser ablation, and the laser stop metal protects the first semiconductor die from the laser ablation.

The second semiconductor die is a bulk acoustic wave (BAW) device.

The method further comprises performing a second die attach process that attaches a first side of BAW device to the second side of the first semiconductor die, and performing a second wire bonding process that connects a second bond wire between a bond pad on a second side of BAW device to a second conductive pad on the first semiconductor die. The stress absorbing material is deposited over the second bond wire.

The method further comprises flip chip bonding the BAW device to the second side of the first semiconductor die so that metal bump bonds electrically couple bond pads on a first side of BAW device to contact pads on the second side of the first semiconductor die. The first side of BAW device faces the second side of the first semiconductor die.

The method further comprises after performing the deposition process, performing a singulation process that separates stacked-die package devices from one another.

### BRIEF DESCRIPTION OF THE DRAWINGS

Having thus described the invention in general terms, reference will now be made to the accompanying drawings, wherein:

FIG. 1 is a cross sectional view of an example stacked-die microresonator leadframe package that includes a bulk acoustic wave (BAW) die mounted on a second semiconductor die.

FIGS. 2A-2F illustrate steps for fabricating a BAW microresonator semiconductor package according to one arrangement.

FIGS. 3A-3G illustrate steps for an alternative process for fabricating a BAW microresonator semiconductor package according to another arrangement.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . .” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Elements that are electrically connected with intervening wires or other conductors are considered to be coupled. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor die” is used herein. A semiconductor die refers to a thin slice of material, such as a crystalline silicon, that is used to fabricate integrated circuits. A large number of integrated circuits may be created on an active surface of the semiconductor wafer. Discrete semiconductor devices can be integrated circuits with hundreds or thousands of transistors coupled to form a functional circuit, for example a microprocessor or memory device. The semiconductor device may also be referred to herein as a semiconductor wafer or an integrated circuit (IC) die.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effect transistor (FET) semiconductor device and a second semiconductor device (such as a gate driver die, or a controller die) can be packaged together to from a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device. In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

The term “bulk acoustic wave (BAW)” is used herein. BAW technology is designed to implement stable, secure, and high-performance communications infrastructure and connectivity. BAW is a micro-resonator technology enabling the integration of high-precision and ultra-low jitter clocks directly into packages that contain other circuits. This allows for cleaner wired and wireless signals to be delivered over networks by a crystal-less package. BAW-based oscillators feature reliable, high-accuracy timing and wake up much faster than quartz crystals. BAW technology can be used to improve network performance and increase immunity to vibration and shock in a wide range of applications. BAW resonator technology enables high-performance, highly accurate resonators. When integrated into a microcontroller package, BAW resonators eliminate the need for external quartz crystals without compromising power, latency or frequency stability. BAW technology is a vital component in advanced filtering solutions for mobile products, as well as the advanced radar, communications systems, and sensor applications.

The term “glob top” is used herein. In packaged integrated circuits, glob top refers to a stress absorbing material that encapsulates all or a portion of a semiconductor die, such as a BAW die. The glob top may encapsulate related wire bonds that electrically connects the semiconductor die to other components. Performance of some devices can be improved by isolating a die within a package from mechanical stress, shock, and/or vibration incident on the outer surfaces of the package. The glob top or stress absorbing material structurally isolates a die from external mechanical stress. The glob top material may be dispensed as a liquid or gel and is subsequently cured using UV, thermal, or time cure processes. The cure process selected depends on the type of glob top material selected. Glob top encapsulants are typically one- or two-part epoxies or UV curable compounds that are specially formulated to flow easily in response to stress applied during application but have rapidly increasing viscosity after placement. This change in viscosity allows the material to flow smoothly into narrow spaces without damaging semiconductor dies or bond wires while preventing the material from flowing beyond the target area. Once cured, glob tops protect die and wire bonds from contaminants and moisture while providing sufficient mechanical support to prevent damage during handling and assembly.

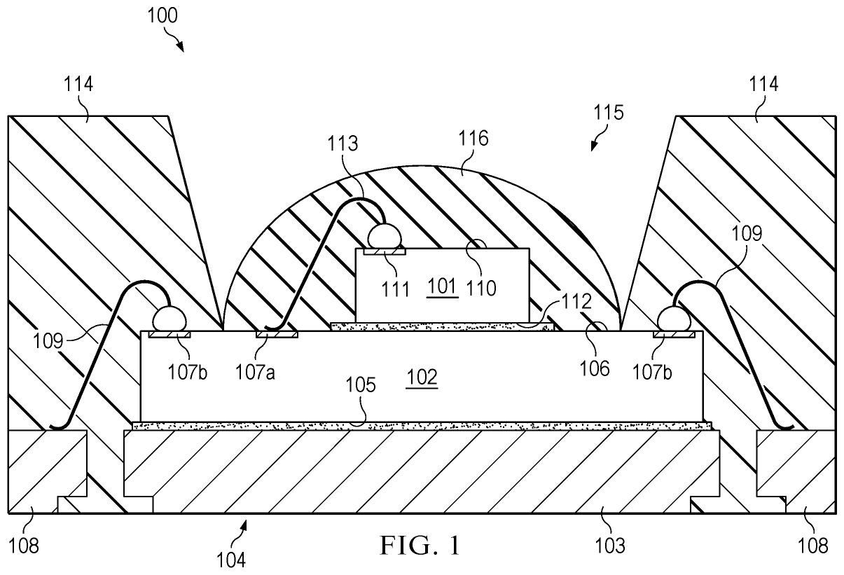

FIG. 1 is a cross sectional view of an example stacked-die microresonator leadframe package 100 that includes a first die 101 mounted on a second semiconductor die 102. The first die 101 is a BAW resonator, which may include a piezoelectric material sandwiched between two electrodes to act as clock source or filter with timing accuracy requirements measured in the parts per million (ppm). Second semiconductor die 102 is mounted to a die attach pad 103, which is a portion of a leadframe 104. The second semiconductor die 102 includes one or more electronic components (not shown), such as transistors, resistors, capacitors, etc. The first semiconductor die 102 has a first (e.g., bottom) side 105 mounted to the die attach pad 103, and a second (e.g., top) side 106 with conductive bond pads 107a, 107b electrically connected to a circuit or component of the second semiconductor die 102.

The example electronic device 100 of FIG. 1 is a four-sided flat no-leads package (e.g., a quad-flat no-leads (QFN) package). The concepts of the present disclosure can be used in other types and forms of electronic device packages, such as dual-flat no-leads (DFN) packages, micro leadframe (MLF) packages, small outline no leads (SON) packages, or other surface mount and non-surface mount electronic device package types and/or forms. In the QFN example of FIG. 1, the electronic device 100 includes leads 108 that are part of leadframe 104. Leads 108 are outwardly spaced apart from respective ones of the four sides of the die attach pad 103. The leads 108 have externally accessible portions for soldering to a host printed circuit board (not shown). Other implementations are possible in which the leads 108 are provided on only a single side of the electronic device 100, or on a different number of sides of the electronic device 100. The electronic device 100 also includes bond wires 109 that are connected between the conductive bond pads 107b of the second semiconductor die 102 and respective leads 108.

The BAW resonator die 101 has a top surface 110 with one or more one or more bond pads 111 and a bottom surface 112 that is mounted on the top side 106 of second semiconductor die 102. The bond pads 111 on BAW resonator die 101 are connected to conductive bond pads 107a on the second semiconductor die 102 using bond wires 113. BAW resonator die 101 may provide a reference oscillator or clock signal to second semiconductor die 102. Although not shown, the BAW resonator die 101 can have more than one bond pad 111, such as to add a ground connection or other connections to second semiconductor die 102.

A mold compound 114 encapsulates some or all of the leadframe 104, second semiconductor die 102, and bond wires 109. Mold compound 114 may be a thermoset epoxy resin mold compound that is applied during a molding process or some other epoxy, plastic, or resin. Die attach pad 103 and leads 108 are exposed through the sidewalls of mold compound 114 for attachment to other devices, such as a printed circuit board (PCB). In other arrangements, leads 108 may have an exposed portion that extends beyond the sidewalls of mold compound 114.

A cavity 115 is formed within mold compound 114 during the manufacturing process. A stress absorbing structure 116 within cavity 115 encapsulates the BAW resonator die 101. The stress absorbing structure 116 functions as a glob top and forms a bubble-like structure over BAW resonator die 101. The stress absorbing structure 116 extends across a portion of the top surface 106 of second semiconductor die 106 and encapsulates all exposed surfaces of BAW resonator die 101, bond pad(s) 111, and bond wire(s) 113.

In one arrangement, the stress absorbing structure 116 is a flexible material that isolates all or a portion of the BAW resonator die 101 from external mechanical stress (e.g., shock and/or vibration) incident on the packaged electronic device 100. One suitable example material for the stress absorbing structure 116 is an epoxy material. In one example, the stress absorbing structure 116 includes a thermally cured epoxy material. In one example, the stress absorbing structure 116 is a low viscosity epoxy encapsulant, such as an epoxy laminate. In other arrangements, stress absorbing structure 116 is a low elastic modulus material, such as silicone rubber. The stress absorbing structure 116 helps isolate stress from the BAW resonator die 101. For example, stress from external forces can transfer stress to the BAW resonator die 101. The stress absorbing structure 116 helps to prevent coupling stresses from the second semiconductor die 102 or the mold compound 114 into the BAW resonator die 101.

In prior semiconductor packages having a BAW resonator die, a glob top of stress absorbing material covered the BAW resonator die, and the package mold compound 114 typically covered and encapsulated the entire glob top. In such designs, package stress (such as stress due to change in temperature) causes a frequency shift in the BAW device oscillator or microresonator, which is a critical item that needs to be controlled within certain limits. The mold compound encapsulating the package and situated above the BAW resonator die directly influences the package stress. The configuration disclosed herein, with a mold-free cavity design, avoids the package stress issues found in prior designs.

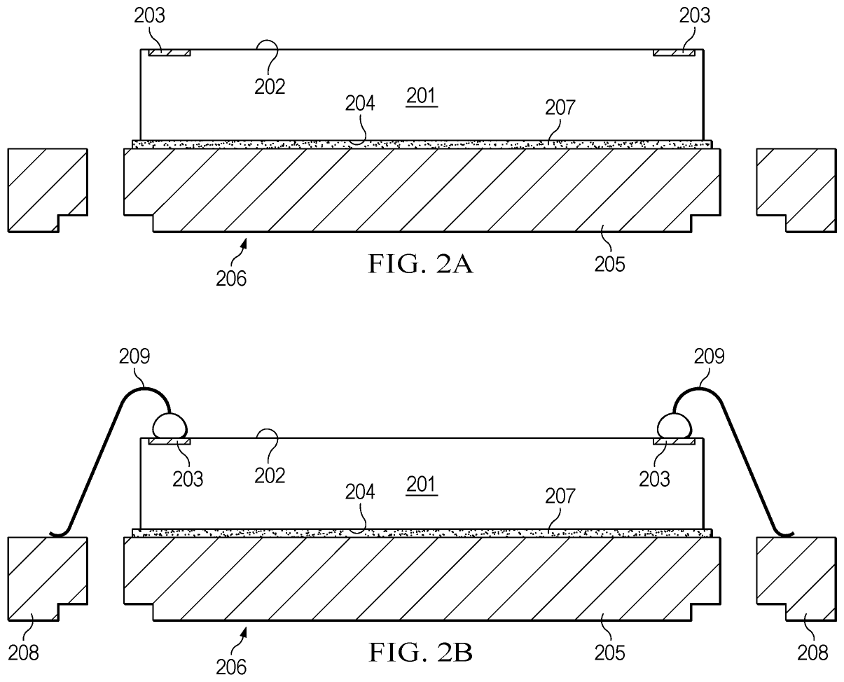

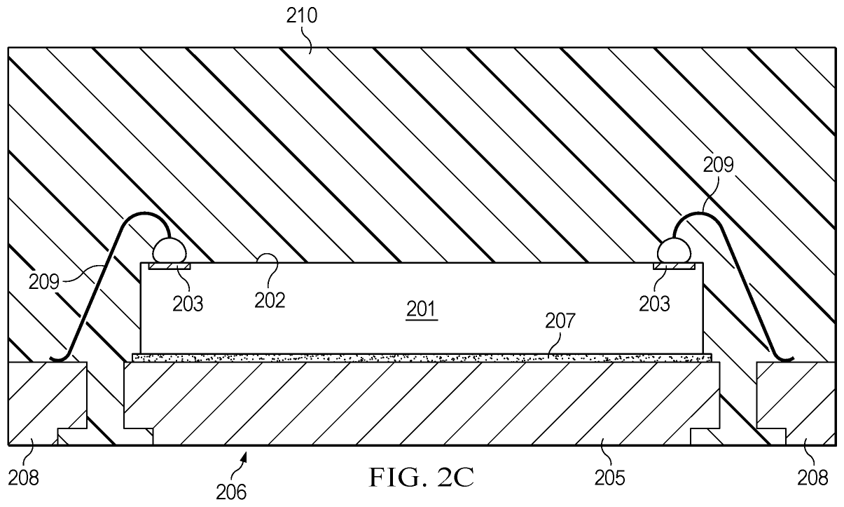

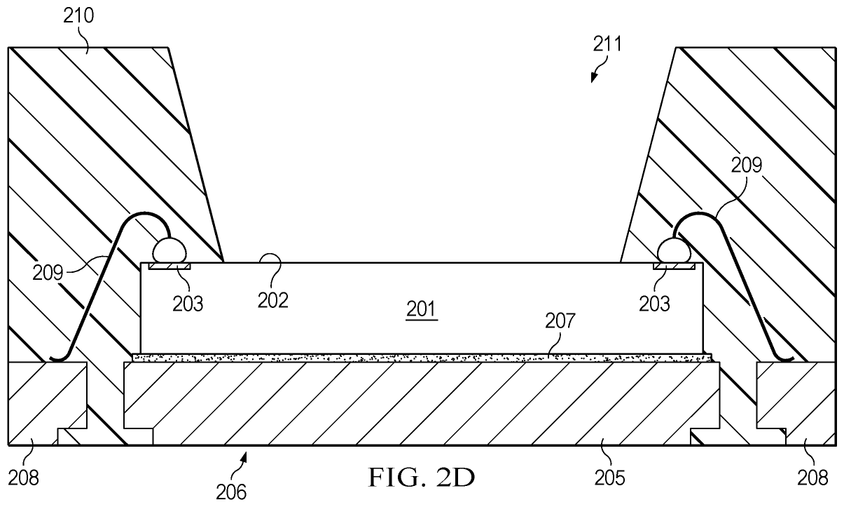

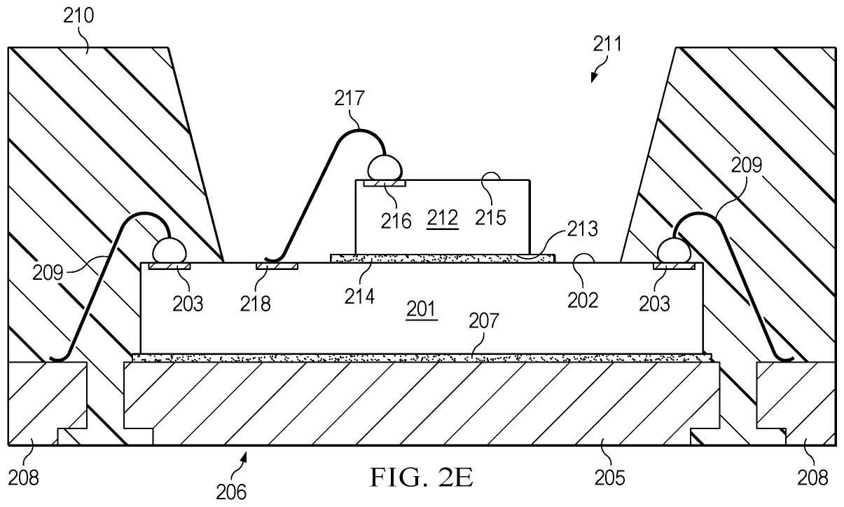

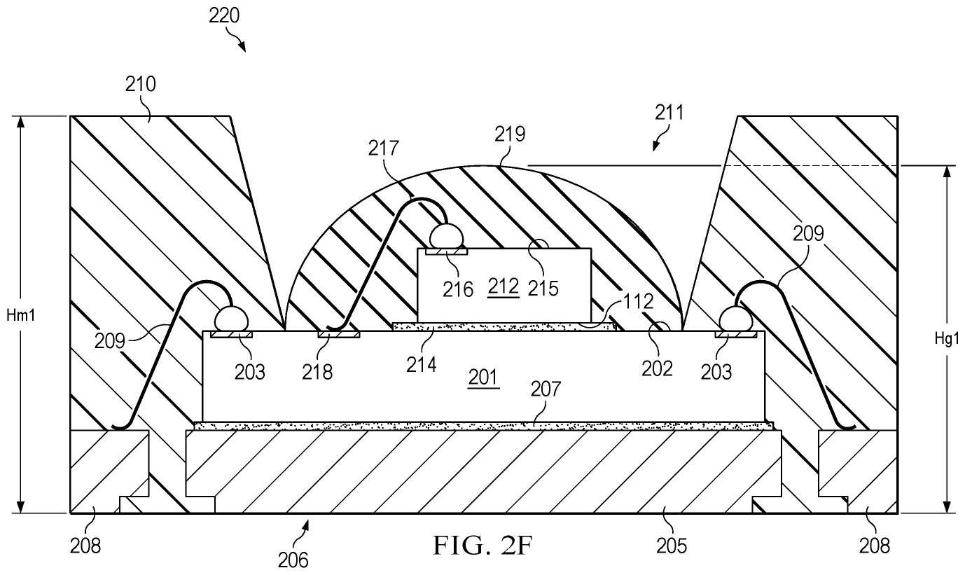

FIGS. 2A-2F illustrate steps for fabricating a BAW microresonator semiconductor package according to one arrangement. These steps can be used in one implementation to fabricate the device 100 described above. The steps may be used to concurrently fabricate multiple packaged electronic devices in a panelized batch process, with individual packaged electronic devices being separated after or near the end of the process.

In FIG. 2A, a semiconductor or IC die 201 has an active surface 202 that is usually the top surface when the semiconductor die 201 is the “face up” configuration. Active surface 202 has bond pads 203 that provide contacts to other circuits and devices. In one arrangement, semiconductor die 201 is a microcontroller for wireless communication or sensing applications. A bottom surface 204 of semiconductor die 201 is mounted on a die attach pad 205 of a leadframe 206 using a die attach paste or die attach film 207.

In FIG. 2B, the bond pads 203 on active surface 202 of the semiconductor die 201 are connected to lead portions 208 of leadframe 206 using bond wires 209. The bond wires 209 electrically connect input or output signals between the leadframe 206 and semiconductor die 201.

In FIG. 2C, a package body is formed by a thermoset epoxy resin mold compound 210 in a molding process. The semiconductor die 201, bond pads 203, bond wires 209, and most of leadframe 206 is encapsulated by mold compound 210. However, a portion of the leads 208 and the die attach pad 205 of the leadframe 206 are not covered during encapsulation in order to expose contacts for connection to other devices and circuits. The molding process may include placing a mold surrounding semiconductor die 201, bond pads 203, bond wires 209, and leadframe 206 and then injecting the mold compound into the mold.

In FIG. 2D, a cavity 211 is created in mold compound 210 by laser ablation. Cavity 211 exposes a portion of the top surface 202 of semiconductor device 201. The sides of semiconductor 201 and operational components, such as bond pads 203 and bond wires 209, remain encapsulated within bond compound 210. In one embodiment, a high power laser ablates the mold compound 210 from the region of cavity 211 into a vapor. A tolerance of +/−10 um has been observed for laser ablation as shown in FIG. 2D, which is sufficient to provide clearance for bond wires 209 or other features that should remain within mold compound 210 and not be exposed in cavity 211.

In FIG. 2E, a BAW die 212 is mounted within cavity 211. BAW die 212 has a bottom side 213 that is attached to top surface 202 of semiconductor die 201 using a die attach paste or film 214. BAW die 212 has a top surface 215 with one or more bond pads 216. Bond wires 217 connect bond pads 216 on BAW die 212 with contact pads 218 on semiconductor die 201.

In FIG. 2F, a BAW microresonator semiconductor package 220 is created by applying a glob top 219 over BAW die 212. The stress absorbing material method may be deposited into the cavity 211 in mold compound 210 to cover by jet printing, for example. The glob top 219 is a stress absorbing structure and may comprise, for example, a thermally cured epoxy material, a low viscosity epoxy encapsulant, an epoxy laminate, or a low elastic modulus material, such as silicone rubber. The glob top encapsulant 219 is placed to improve the frequency shift margins for BAW die 212. The glob top 219 covers all exposed aspects of BAW die 212, including bond pad 216 and bond wire 217. The glob top 219 also encapsulates any portion of surface 202 of semiconductor die 201 that was exposed by the laser ablation that formed cavity 211. The height Hg1 of glob top material 219 is less than the height Hm1 of mold compound 210 so that glob top 219 is not exposed above the top opening of cavity 211.

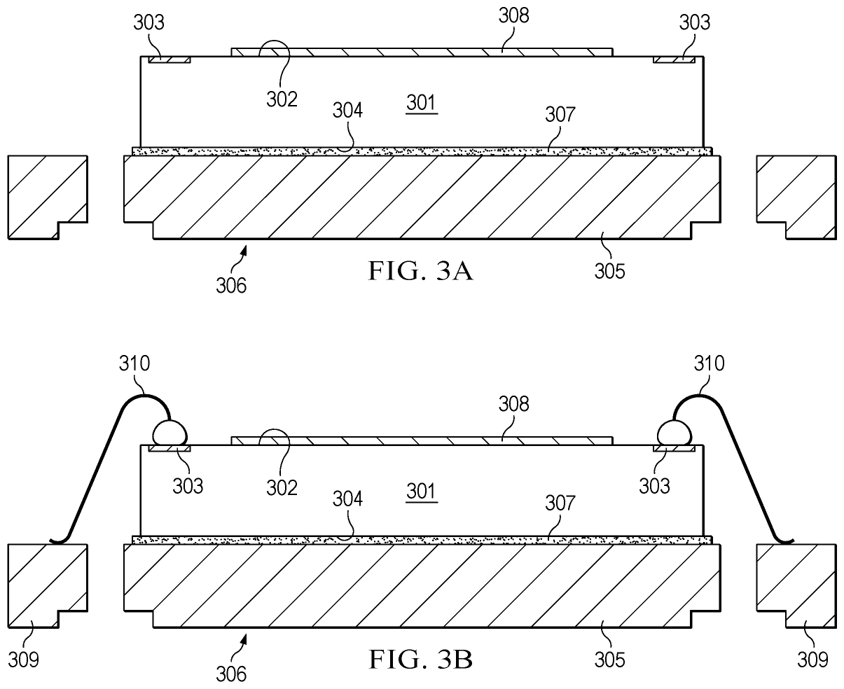

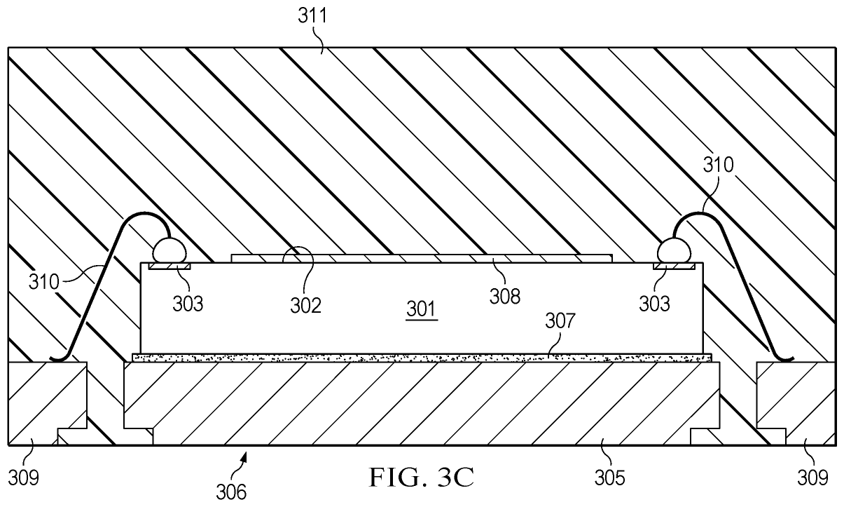

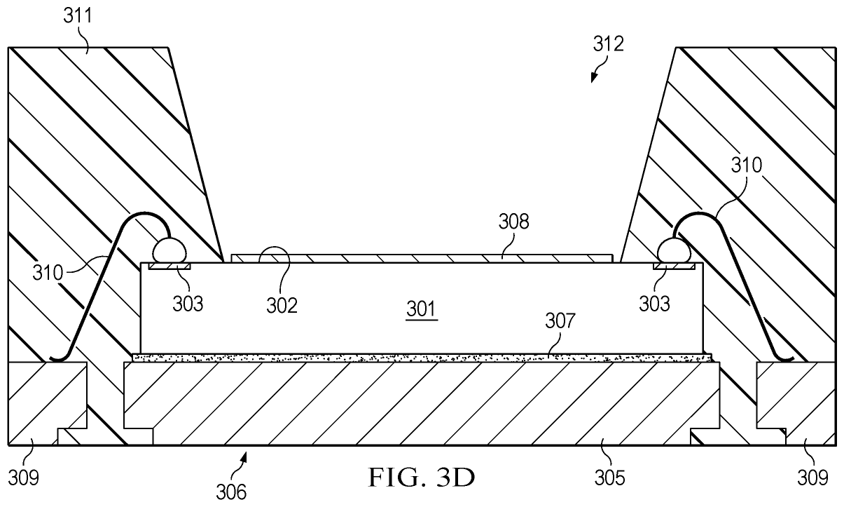

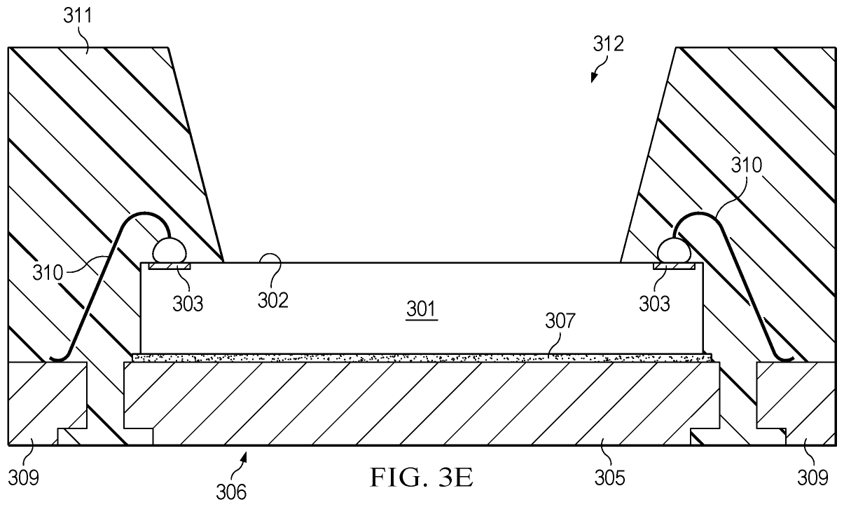

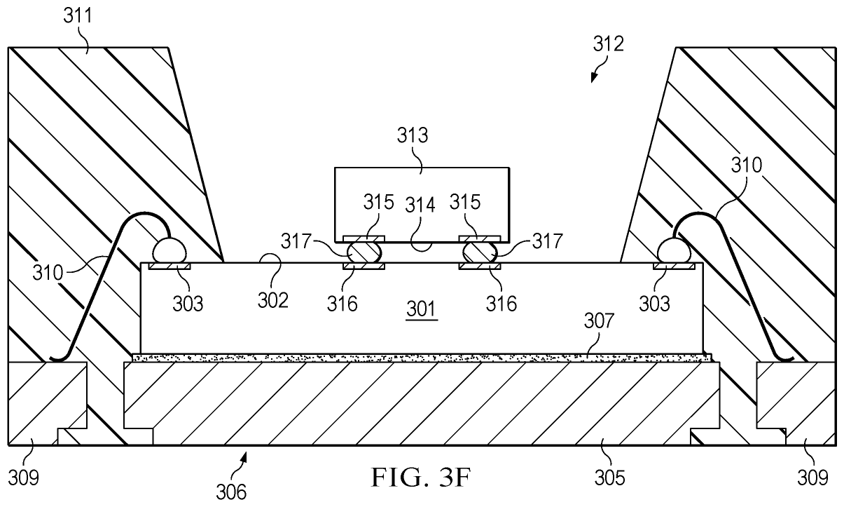

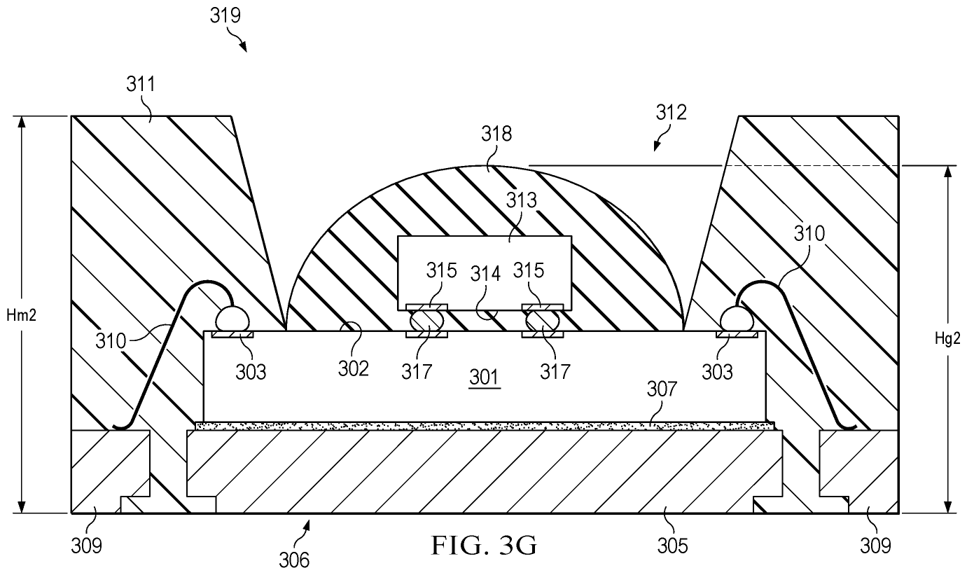

FIGS. 3A-3G illustrate steps for an alternative process for fabricating a BAW microresonator semiconductor package according to another arrangement. These steps can be used in one implementation to fabricate the device 100 described above. The steps may be used to concurrently fabricate multiple packaged electronic devices in a panelized batch process, with individual packaged electronic devices being separated after or near the end of the process.

In FIG. 3A, a semiconductor or IC die 301 has an active surface 302. Active surface 302 has bond pads 303 that provide contacts to other circuits and devices. In one arrangement, semiconductor die 301 is a microcontroller for wireless communication or sensing applications. A bottom surface 304 of semiconductor die 301 is mounted on a die attach pad 305 of a leadframe 306 using a die attach paste or die attach film 307. FIG. 3A differs from FIG. 2A by the addition of a laser stop metal 308 that has been deposited on active surface 302 of semiconductor die 301.

In FIG. 3B, the bond pads 303 on active surface 302 of the semiconductor die 301 are connected to lead portions 309 of leadframe 306 using bond wires 310. The bond wires 310 electrically connect input or output signals between the leadframe 306 and semiconductor die 301.

In FIG. 3C, a package body is formed by a thermoset epoxy resin mold compound 311 in a molding process. The semiconductor die 301, bond pads 303, bond wires 310, and most of leadframe 306 is encapsulated by mold compound 311. In this configuration, the laser stop metal 308 is also covered by mold compound 311. A portion of the leads 309 and the die attach pad 305 of the leadframe 306 are not covered during encapsulation in order to expose contacts for connection to other devices and circuits.

In FIG. 3D, a cavity 312 is created in mold compound 311 by laser ablation. The top surface 302 of semiconductor die 301 is protected from the laser by laser stop metal 308. Cavity 312 exposes laser stop metal 308 on the top surface 302 of semiconductor device 301. The sides of semiconductor 301 and operational components, such as bond pads 303 and bond wires 310, remain encapsulated within bond compound 311.

In FIG. 3E, the laser stop metal 308 has been removed by a chemical process, such as a wet cleaning or rinsing process with a solution capable of oxidizing the laser stop metal 308 on surface 302. In another arrangement, a dummy plated material that is electrically isolated from the semiconductor die 301 may be used in place of the laser stop metal 308.

In FIG. 3F, a BAW die 313 is mounted within cavity 312 on semiconductor die 301. BAW die 313 has an active side 314 with contacts 315. BAW die 313 is flip-chip mounted so that contacts 315 on BAW die 313 are bonded to contacts 316 on semiconductor die 301 by bumps 317. The bumps 317 can comprise a copper (Cu) post with a different metal cap thereon. A typical solder bump material is a Cu post with a nickel-palladium (Ni—Pd) cap or silver-tin alloy (AgSn) solder material cap. The bumps 317 may can also be gold (Au) bumps.

In FIG. 3G, a BAW microresonator semiconductor package 319 is created by applying a glob top 318 BAW die 313. The glob top encapsulant 318 is placed to improve the frequency shift margins for BAW die 313. The glob top 318 is a stress absorbing structure and may comprise, for example, a thermally cured epoxy material, a low viscosity epoxy encapsulant, an epoxy laminate, or a low elastic modulus material, such as silicone rubber. The glob top 318 covers all exposed aspects of BAW die 313, including bond pads 315 and bumps 317. The glob top 318 also encapsulates any portion of surface 302 of semiconductor die 301 that was exposed by the laser ablation that formed cavity 312 and the chemical removal of the laser stop metal. The glop top material 318 also fills under BAW die 313 between surface 314 and semiconductor surface 302 in and around bumps 317. The height Hg2 of glob top material 318 is less than the height Hm2 of mold compound 311 so that glob top 320 is not exposed above the top opening of cavity 312.

Multiple devices may be manufactured at the same time on a leadframe sheet. After such processes are completed, the semiconductor wafer, leadframe, and mold compound are severed (“singulated” or “diced”) with a cutting tool, such as a saw or laser, into separate semiconductor packages. Each semiconductor package including a singulated leadframe, at least one IC die, electrical connections between the die and leadframe (e.g., a roughened conductive bump), and the mold compound which covers at least part of these structures.

In one arrangement, an electronic package, such as a semiconductor device or semiconductor package, comprises a segment of a leadframe having a die attach pad and one or more leads and a semiconductor die electrically connected to the die attach pad. A BAW device is attached to, and electrically connected to, the semiconductor die. A mold compound surrounds the first semiconductor die and covers portions of the leadframe and a first portion of a top surface of the semiconductor die. The mold compound has a cavity area wherein the mold compound has been removed from the cavity area or was never formed in the cavity area. The mold compound does not cover the BAW device or a second portion of the top surface of the semiconductor die within the cavity area. A glob top material is disposed within the cavity area (i.e., the cavity area is at least partially filled with the glob top material). The glob top material covers the BAW device and the second portion of the top of the semiconductor die (i.e., the glob top material covers areas that are not covered by the mold compound). The semiconductor die is electrically connected to the one or more leads by bond wires that are encapsulated by the mold compound. The glob top is a stress absorbing material that isolates the BAW device from stresses and vibrations in the electronic package. The glob top is a low elastic modulus material that is different from a material used for the mold compound.

The cavity area has a first height above the semiconductor die. The glob top material has a second height above the semiconductor die that is less than the first height (i.e., the glob top material does not protrude above the top surface of the mold compound). The glob top material does not fill the cavity area in the mold compound. The mold compound does not cover a top surface of the glob top material.

The BAW device has as top surface and a bottom surface. In one configuration, the bottom surface is attached to the top surface of the semiconductor die. The top surface has one or more bond pads. The one or more bond pads are electrically connected to contact pads on the semiconductor die by bond wires.

In another configuration, the BAW device is flip-chip mounted on the semiconductor die. The electronic package further comprises bond pads on an active surface of the BAW device. The active surface of the BAW device faces the top surface of the semiconductor die. Contact pads are on the top surface of the semiconductor die. Bumps electrically connect the bond pads to the contact pads.

A example method for assembling a stacked-die package comprises performing a first die attach process that attaches a first side of a first semiconductor die to a die attach pad of a leadframe, performing a first wire bonding process that connects a first bond wire between a first conductive pad of the first semiconductor die to a lead of the leadframe, and performing a molding process that encloses a portion of the die attach pad, a portion of the lead, first semiconductor die, and the first bond wire in a mold compound. The method further comprises creating a cavity in the mold compound, the cavity extending from a second side of the first semiconductor die to a top of the mold compound, performing a second die attach process that attaches a second semiconductor die to the second side of the first semiconductor die; and performing a deposition process that deposits a stress absorbing material in the cavity to cover the second semiconductor die. The second semiconductor die is a BAW device. After performing the deposition process, a singulation process is performed to separate stacked-die package devices from one another.

The cavity in the mold compound may be created using laser ablation. The method further comprises applying a laser stop metal to a portion of the second surface of the first semiconductor die before the molding process and chemically removing an exposed segment of the laser stop metal after the cavity has been created. The laser stop metal protects the first semiconductor die from the laser ablation.

In one arrangement, the method further comprises performing a second die attach process that attaches a first side of BAW device to the second side of the first semiconductor die and performing a second wire bonding process that connects a second bond wire between a bond pad on a second side of BAW device to a second conductive pad on the first semiconductor die. The stress absorbing material is deposited over the second bond wire.

In another arrangement, the method further comprises flip chip bonding the BAW device to the second side of the first semiconductor die so that metal bump bonds electrically couple bond pads on a first side of BAW device to contact pads on the second side of the first semiconductor die, wherein the first side of BAW device faces the second side of the first semiconductor die.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. An electronic package, comprising:
a segment of a leadframe having a die attach pad and one or more leads;
a semiconductor die electrically connected to the die attach pad;
a bulk acoustic wave (BAW) device attached to, and electrically connected to, the semiconductor die;
a mold compound surrounding the first semiconductor die and covering portions of the leadframe and a first portion of a top surface of the semiconductor die;
a cavity area in the mold compound, wherein the mold compound does not cover the BAW device or a second portion of the top surface of the semiconductor die within the cavity area; and
a glob top material disposed within the cavity area, the glob top material covering the BAW device and the second portion of the top of the semiconductor die.

2. The electronic package of claim 1, wherein the cavity area has a first height above the semiconductor die and the glob top material has a second height above the semiconductor die that is less than the first height.

3. The electronic package of claim 1, wherein the glob top material does not fill the cavity area in the mold compound.

4. The electronic package of claim 1, wherein the mold compound does not cover a top surface of the glob top material.

5. The electronic package of claim 1, wherein the semiconductor die is electrically connected to the one or more leads by bond wires that are encapsulated by the mold compound.

6. The electronic package of claim 1, wherein the BAW device has as top surface and a bottom surface, the bottom surface attached to the top surface of the semiconductor die, the top surface having one or more bond pads, the one or more bond pads electrically connected to contact pads on the semiconductor die by bond wires.

7. The electronic package of claim 1, wherein the BAW device is flip-chip mounted on the semiconductor die.

8. The electronic package of claim 7, further comprising:
bond pads on an active surface of the BAW device, the active surface of the BAW device facing the top surface of the semiconductor die;
contact pads on the top surface of the semiconductor die; and
bumps electrically connecting the bond pads to the contact pads.

9. The electronic package of claim 1, wherein the glob top is a stress absorbing material that isolates the BAW device from stresses and vibrations in the electronic package.

10. The electronic package of claim 1, wherein the glob top is a low elastic modulus material that is different from a material used for the mold compound.

11. The electronic package of claim 1, wherein electronic package is a quad-flat no-leads (QFN) package.

12. A method of assembling a stacked-die package, comprising:
performing a first die attach process that attaches a first side of a first semiconductor die to a die attach pad of a leadframe;
performing a first wire bonding process that connects a first bond wire between a first conductive pad of the first semiconductor die to a lead of the leadframe;
performing a molding process that encloses a portion of the die attach pad, a portion of the lead, first semiconductor die, and the first bond wire in a mold compound;
creating a cavity in the mold compound, the cavity extending from a second side of the first semiconductor die to a top of the mold compound;
performing a second die attach process that attaches a second semiconductor die to the second side of the first semiconductor die; and
performing a deposition process that deposits a stress absorbing material in the cavity to cover the second semiconductor die.

13. The method of claim 12, wherein the cavity in the mold compound is created using laser ablation.

14. The method of claim 12, further comprising:
applying a laser stop metal to a portion of the second surface of the first semiconductor die before the molding process; and
chemically removing an exposed segment of the laser stop metal after the cavity has been created.

15. The method of claim 14, wherein the cavity in the mold compound is created using laser ablation, and wherein the laser stop metal protects the first semiconductor die from the laser ablation.

16. The method of claim 12, wherein the second semiconductor die is a bulk acoustic wave (BAW) device.

17. The method of claim 16, further comprising:
performing a second die attach process that attaches a first side of BAW device to the second side of the first semiconductor die; and
performing a second wire bonding process that connects a second bond wire between a bond pad on a second side of BAW device to a second conductive pad on the first semiconductor die.

18. The method of claim 17, wherein the stress absorbing material is deposited over the second bond wire.

19. The method of claim 16, further comprising:
flip chip bonding the BAW device to the second side of the first semiconductor die so that metal bump bonds electrically couple bond pads on a first side of BAW device to contact pads on the second side of the first semiconductor die, wherein the first side of BAW device faces the second side of the first semiconductor die.

20. The method of claim 12, further comprising:
after performing the deposition process, performing a singulation process that separates stacked-die package devices from one another.
